(19) United States
(12) Patent Application Publication
(10) Pub. No.: US 2008/0211115 A1
(43) Pub. Date: Sep. 4, 2008

(54) Semiconductor structure and an apparatus and a method for producing a semiconductor structure

(76) Inventors: Olaf Storbeck, Dresden (DE); Regina Hayn, Baernsdorf (DE)

Correspondence Address: SLATER & MATSIL LLP, 17950 PRESTON ROAD, SUITE 1000, DALLAS, TX, 75252, US

(21) Appl. No.: 11/713,568

(22) Filed: Mar. 2, 2007

(51) Int. Cl. H01L 23/29

(52) U.S. Cl. 257/788; 118/640; 438/778; 257/E21.002

(57) ABSTRACT

In a method of forming an insulating layer on a silicon substrate, the silicon substrate is arranged inside a process chamber. An oxide layer is formed on the substrate's surface. An electrical field is applied and an oxygen particles containing plasma is provided above the substrate's surface. The electrical field accelerates the oxygen particles in the direction of the surface so that the oxygen particles penetrate inside the substrate and form said oxide layer. Thereafter, the stoichiometry of the oxide layer is modified. A nitrogen particles containing plasma is provided above the substrate's surface. The electrical field accelerates the nitrogen particles in the direction of the surface so that the nitrogen particles penetrate inside the oxide layer and modify the stoichiometry of the oxide layer. The step of forming the oxide layer and the step of modifying the stoichiometry are carried out inside the same process chamber.

### BACKGROUND

The invention is related to an apparatus and a method of producing a semiconductor structure. More particularly, the invention is directed to an apparatus and a method wherein an insulating layer is fabricated on a silicon substrate.

### SUMMARY OF THE INVENTION

An embodiment of the invention relates to a method of forming an insulating layer on a silicon substrate comprising the steps of: arranging the silicon substrate inside a process chamber; forming an oxide layer on the substrate's surface wherein an electrical field is applied and wherein an oxygen particles containing plasma is provided above the substrate's surface, the electrical field accelerating the oxygen particles in the direction of the surface wherein the oxygen particles penetrate inside the substrate and form said oxide layer; thereafter, modifying the stoichiometry of the oxide layer wherein a nitrogen particles containing plasma is provided above the substrate's surface; the electrical field accelerating the nitrogen particles in the direction of the surface wherein the nitrogen particles penetrate inside the oxide layer and modify the stoichiometry of the oxide layer; wherein the step of forming the oxide layer and the step of modifying the stoichiometry are carried out inside the same process chamber.

According to one aspect of the invention the step of forming the oxide layer and the step of modifying the stoichiometry of the oxide layer are carried out inside the same process chamber. By using the same process chamber for both steps the cost efficiency can be significantly enhanced compared to methods which carry out both steps in different process chambers.

Additionally, the method may be carried out at a relatively low temperature as the oxygen and nitrogen particles are accelerated in the direction of the surface by an electrical field.

Another embodiment of the invention is directed to an apparatus comprising a first process chamber and a second process chamber wherein the first process chamber is adapted to perform the following steps: forming an oxide layer on the substrate's surface wherein an electrical field is applied and wherein an oxygen particles containing plasma is provided above the substrate's surface, the electrical field accelerating the oxygen particles in the direction of the surface wherein the oxygen particles penetrate inside the substrate and form said oxide layer; and modifying the stoichiometry of the oxide layer wherein a nitrogen particles containing plasma is provided above the substrate's surface; the electrical field accelerating the nitrogen particles in the direction of the surface wherein the nitrogen particles penetrate inside the oxide layer and modify the stoichiometry of the oxide layer; and wherein the second process chamber is adapted to subject the insulating layer to a post-treatment procedure.

Furthermore, as an embodiment, the invention provides a semiconductor device comprising a silicon substrate and an insulating layer thereon. The insulating layer is made by using the method as discussed above.

### BRIEF DESCRIPTION OF THE DRAWINGS

In order that the manner in which the above-recited and other advantages of the invention are obtained will be readily understood, a more particular description of the invention briefly described above will be rendered by reference to specific embodiments thereof which are illustrated in the appended drawings. Understanding that these drawings depict only typical embodiments of the invention and are not therefore to be considered to be limiting of its scope, the invention will be described and explained with additional specificity and detail through the use of the accompanying drawings in which:

FIG. 1 shows an exemplary embodiment of the inventive apparatus;

FIGS. 2-3 show a process flow of an exemplary embodiment of the inventive method;

FIG. 4 shows a first exemplary embodiment of a semiconductor device fabricated according to the invention; and

FIG. 5 shows a second exemplary embodiment of a semiconductor device fabricated according to the invention.

### DETAILED DESCRIPTION OF ILLUSTRATIVE EMBODIMENTS

The preferred embodiment of the present invention will be best understood by reference to the drawings, wherein like parts are designated by like numerals throughout.

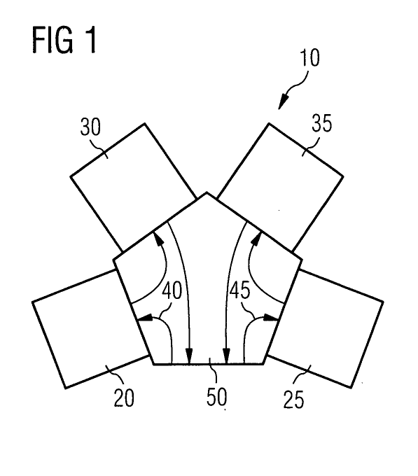

It will be readily understood that the process steps of the present invention, as generally described and illustrated in the figures herein, could vary in a wide range of different process steps. Thus, the following more detailed description of the exemplary embodiments of the present invention, as represented in FIGS. 1-5 is not intended to limit the scope of the invention, as claimed, but is merely representative of presently preferred embodiments of the invention.

The present invention relates to a method for fabricating a semiconductor device. As an exemplary embodiment of the invention a fabrication of a gate stack layer for a field effect transistor is described hereinafter. The invention applies to other technologies as well.

FIG. 1 shows an exemplary embodiment of an apparatus 10 which is adapted to form an insulating layer on a silicon substrate. The apparatus 10 comprises two first chambers 20 and 25 for plasma oxidation and plasma nitridation. Furthermore, the apparatus comprises two second chambers 30 and 35 for a rapid thermal post anneal step.

As indicated by arrows 40 and 45, a substrate may be either processed in chambers 20 and 30 or 25 and 35 after inserting the substrate into the apparatus through access 50. The apparatus as shown in FIG. 1 allows for two independent process flows at the same time.

In the following, the process steps for fabricating an insulating layer on a silicon substrate are explained with regard to chambers 20 and 30. Of course, chambers 25 and 35 could be used instead or simultaneously for processing further substrates in the same manner or using a different process.

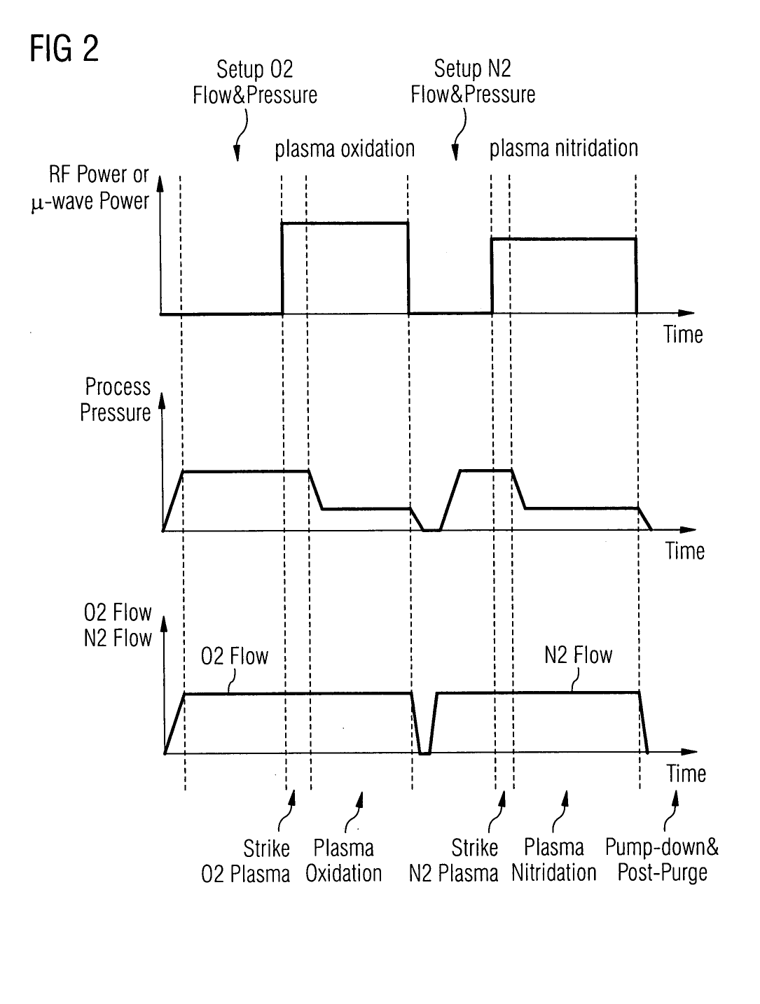

FIG. 2 indicates an embodiment of how to use the first process chamber 20. In a first process step, a silicon substrate is arranged inside the process chamber 20. Then, an oxide layer is formed on the substrate's surface wherein an electrical field is applied and wherein an oxygen particles containing plasma is provided above the substrate's surface. The electrical field accelerates the oxygen particles in the direction to the substrate's surface such that the oxygen particles penetrate inside the substrate and form an oxide layer. This first step is referred to as “plasma oxidation” in FIG. 2.

Thereafter, the stoichiometry of the oxide layer is modified. A nitrogen particles containing plasma is provided above the substrate's surface. The electrical field accelerates the nitrogen particles in the direction to the surface such that the nitrogen particles penetrate inside the oxide layer and modify the stoichiometry. This second step is called “plasma nitridation” in FIG. 2.

As both kinds of particles, i.e. the oxygen and nitride particles, are accelerated by an electric field versus the substrate, the oxidation and nitridation will take place at a relatively low temperature compared to other oxidation and nitridation methods. Preferably, the temperatures during oxidation and/or nitridation are below about 400° C.

Due to the acceleration of particles the method as described above allows the formation of an oxide layer at a temperature that is significantly lower than those otherwise necessary to form gate dielectrics such as a thermal oxide in a standard way. For example, a thermal oxidation usually requires an oxidation temperature of at least 700° C. in order to achieve a sufficient oxidation rate. In contrast thereto, the method described herewith provides a reasonable oxidation speed at a temperature of about 400° C. and below.

The sequence of process steps is briefly summarized below:

1) wafer in

2a) O₂ flow and pressure setup

2b) O₂ purge

2c) strike oxygen plasma

2d) plasma oxidation

3) RF or microwave power off

4) pump-down

6a) N₂ flow and pressure setup

6b) N₂ purge

6c) strike nitrogen plasma

6d) plasma nitridation

7) RF or microwave power off

8) equalize pressure and purge

9) wafer out

Process steps 2a)-2d) refer to the plasma oxidation whereas process steps 6a)-6d) refer to the plasma nitridation.

FIG. 3 shows a graph of the resulting oxide thickness versus the process time for different RF (radio frequency) power values. It can be seen that the oxidation velocity increases with larger RF values. A preferable process window is indicated by reference numeral 100. The process pressure inside the chamber 20 is preferably between 10 and 50 mTorr.

After removing the substrate from the first chamber 20 it is transferred to the second chamber 30 for a “thermal post processing step”. Inside the second chamber 30 the substrate and the insulating layer thereon are, for example, heated to a temperature of between about 700° C. and about 1100° C., preferably in oxygen atmosphere.

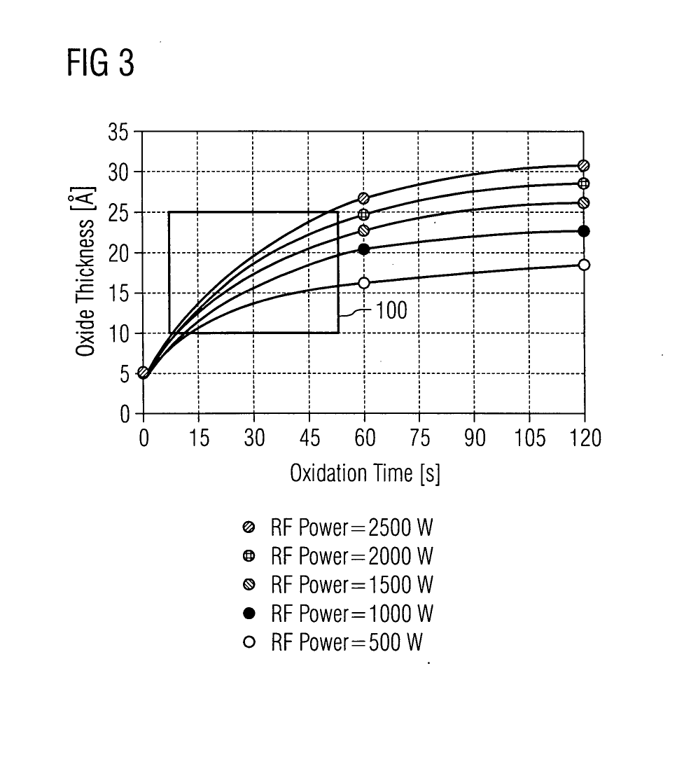

FIG. 4 shows an exemplary embodiment of the resulting structure. An insulating layer 200 is depicted on top of a substrate surface 210. The substrate is marked by reference numeral 220. The insulating layer 200 comprises an oxide layer 310 and a layer 320 with a modified stoichiometry. The layer 320 can be an oxynitride layer.

In FIG. 4 the oxynitride layer 320 is disposed over the oxide layer 310. This structure may be made by using a relatively low electrical acceleration field, which accelerates the nitrogen particles. This prevents the nitride particles from penetrating too deeply into the oxide layer 310 and from reaching the substrate surface 210.

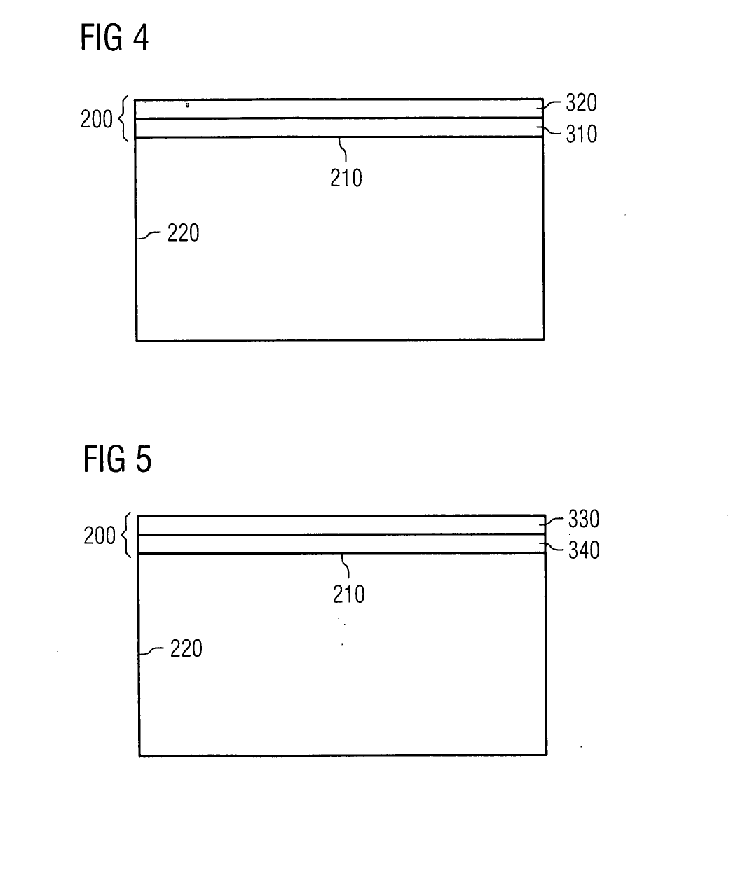

Instead, a structure as shown in FIG. 5 may be made by using a relatively strong electrical acceleration field for accelerating the nitrogen particles. A strong electrical acceleration field will allow the nitride particles to penetrate deeply into the oxide layer and to reach the substrate surface 210. As a result, a bottom portion 340 will then have a higher nitrogen concentration compared to a top portion 330.

Furthermore, both steps, the plasma oxidation and plasma nitridation, could be combined in a single step, where the oxygen and nitrogen particles are introduced simultaneously into the chamber 20. During this step the formation of silicon oxide and silicon nitride takes place at the same time. The partial pressure ratio of the oxygen and nitrogen particles in the process chamber during that step can be used to adjust the stoichiometry of the resulting oxynitride layer, i.e., the ratio silicon to oxygen to nitrogen within the layer.

Although the present invention and its advantages have been described in detail, it should be understood that various changes, substitutions and alterations can be made herein without departing from the spirit and scope of the invention as defined by the appended claims.

What is claimed is:

1. A method of forming an insulating layer over a silicon substrate, the method comprising:
arranging the silicon substrate inside a process chamber;
forming an oxide layer at a substrate surface, wherein an electrical field is applied and wherein a plasma that contains oxygen containing particles is provided above the substrate surface, the electrical field accelerating the oxygen particles in direction of the surface; and
thereafter, modifying the stoichiometry of the oxide layer, wherein a plasma that contains nitrogen containing particles is provided above the substrate surface, the electrical field accelerating the nitrogen particles in direction of the surface;
wherein forming the oxide layer and modifying the stoichiometry are carried out inside the process chamber.

2. The method of claim 1, wherein forming the oxide layer and modifying the stoichiometry are carried out during the same process cycle.

3. The method of claim 2, wherein forming the oxide layer and modifying the stoichiometry are carried out simultaneously.

4. The method of claim 2, wherein forming the oxide layer and modifying the stoichiometry are carried out after one another during the same process cycle.

5. The method of claim 4, wherein accelerating oxygen particles includes accelerating oxygen ions.

6. The method of claim 5, wherein accelerating nitrogen particles includes accelerating nitrogen ions.

7. The method of claim 1, wherein forming the oxide layer is carried out at temperatures below about 400° C.

8. The method of claim 1, wherein modifying the stoichiometry is carried out at temperatures below about 400° C.

9. The method of claim 8, wherein modifying the stoichiometry yields an oxynitride layer that forms said insulating layer.

10. The method of claim 8, wherein modifying the stoichiometry yields a composite layer comprising a nitride layer and a modified oxide layer, the composite layer forming said insulating layer.

11. The method of claim 10, wherein the nitride layer is arranged over the oxide layer.

12. The method of claim 10, wherein the nitride layer is arranged below the oxide layer.

13. The method of claim 1, further comprising subjecting the insulating layer to a post-treatment procedure.

14. The method of claim 13, wherein the post-treatment procedure comprises exposing the insulating layer to an ambient containing at least one element selected from the group consisting of oxygen and nitrogen.

15. The method of claim 12, wherein the post-treatment procedure comprises annealing the insulating layer.

16. The method of claim 15, wherein the insulating layer is annealed at a temperature between 700° C. and 1100° C.

17. The method of claim 7, wherein the plasma that contains oxygen particles and the plasma that contains nitrogen particles are each formed at a pressure between 10 and 50 mTorr.

18. A method of forming an insulating layer on a silicon substrate, the method comprising:
arranging the silicon substrate inside a process chamber;
providing an oxygen ions containing plasma above the substrate and applying an electrical field, the electrical field causing oxygen ions to be implanted in the substrate; and
thereafter, providing a nitrogen ions containing plasma above the substrate and applying an electrical field, the electrical field causing nitrogen ions to be implanted in the substrate;
wherein the oxygen ions and the nitrogen ions are implanted in the same process chamber.

19. The method of claim 18, wherein the oxygen ions and the nitrogen ions are implanted at temperatures below 400° C.

20. The method of claim 19, wherein the implanted oxygen ions and nitrogen ions form an oxynitride layer.

21. The method of claim 19, wherein the implanted oxygen ions and nitrogen ions form a composite layer comprising a nitride layer and an oxide layer.

22. The method of claim 21, wherein the nitride layer is arranged above the oxide layer.

23. The method of claim 21, wherein the nitride layer is arranged below the oxide layer.

24. The method of claim 19, wherein the implanted oxygen ions and nitrogen ions form an insulating layer, the method further comprising subjecting the insulating layer to a post-treatment procedure.

25. The method of claim 24, wherein the post-treatment procedure comprises exposing the insulating layer to an oxygen containing ambient.

26. The method of claim 24, wherein the post-treatment procedure comprises exposing the insulating layer to an oxygen and nitrogen containing ambient.

27. The method of claim 26, wherein the post-treatment procedure comprises annealing the insulating layer inside said oxygen and nitrogen containing ambient.

28. The method of claim 27, wherein the insulating layer is annealed at a temperature between 700° C. and 1100° C.

29. The method of claim 18, wherein the oxygen ions containing plasma and the nitrogen ions containing plasma are each formed at a pressure between 10 and 50 mTorr.

30. A semiconductor device comprising a silicon substrate and an insulating layer thereon, the insulating layer being formed by a method comprising:
arranging the silicon substrate inside a process chamber;
forming an oxide layer at a substrate surface, wherein an electrical field is applied and wherein a plasma that contains oxygen containing particles is provided above the substrate surface, the electrical field accelerating the oxygen particles in direction of the surface; and
thereafter, modifying the stoichiometry of the oxide layer, wherein a plasma that contains nitrogen containing particles is provided above the substrate surface, the electrical field accelerating the nitrogen particles in direction of the surface;
wherein forming the oxide layer and modifying the stoichiometry are carried out inside the process chamber.

31. The semiconductor device according to claim 30 wherein the insulating layer is a gate dielectric layer of a field effect transistor.

32. A semiconductor device comprising a silicon substrate and an insulating layer thereon, the insulating layer being formed by a method comprising:
arranging the silicon substrate inside a process chamber;
providing an oxygen ions containing plasma above the substrate and applying an electrical field, the electrical field causing oxygen ions to be implanted in the substrate; and
thereafter, providing a nitrogen ions containing plasma above the substrate and applying an electrical field, the electrical field causing nitrogen ions to be implanted in the substrate;
wherein the oxygen ions and the nitrogen ions are implanted in the same process chamber.

33. The semiconductor device according to claim 32 wherein the insulating layer is a gate dielectric layer of a field effect transistor.

34. An apparatus comprising a first process chamber and a second process chamber
wherein the first process chamber is adapted to perform the following steps:
forming an oxide layer on a substrate surface, wherein an electrical field is applied and wherein an oxygen particles containing plasma is provided above the substrate surface, the electrical field accelerating oxygen particles in a direction of the surface so that oxygen particles penetrate inside the substrate and form said oxide layer; and
modifying the stoichiometry of the oxide layer, wherein a nitrogen particles containing plasma is provided above the substrate surface, the electrical field accelerating nitrogen particles in the direction of the surface so that nitrogen particles penetrate inside the oxide layer and modify the stoichiometry of the oxide layer;
and wherein the second process chamber is adapted to subject the insulating layer to a post-treatment procedure.

35. The apparatus according to claim 34, wherein the post-treatment procedure comprises an anneal step.

36. The apparatus according to claim 34 wherein the post-treatment procedure comprises exposing the substrate to an ambient containing oxygen and/or nitrogen.
